(19) United States
(12) Patent Application Publication
(10) Pub. No.: US 2025/0151420 A1
(43) Pub. Date: May 8, 2025

(54) Avalanche Photodiode (APD) with Uniform Optical Absorption

(71) Applicant: Ayar Labs, Inc., San Jose, CA (US)

(72) Inventor: Dries Vercruysse, Millbrae, CA (US)

(21) Appl. No.: 18/928,164

(22) Filed: Oct. 27, 2024

Related U.S. Application Data
(60) Provisional application No. 63/547,174, filed on Nov. 3, 2023.

(51) Int. Cl. H01L 31/107; H01L 31/0232; H01L 31/028; H01L 31/18

(52) U.S. Cl. CPC H10F 30/225; H10F 71/1212; H10F 77/122; H10F 77/413

(57) ABSTRACT

An integrated photodetector device includes a silicon region and an optically absorptive region formed within the silicon region. The optically absorptive region has a light incidence end and a distal end, where a light propagation direction extends from the light incidence end to the distal end. A first doped region is formed within the silicon region on a first side of the optically absorptive region. A second doped region is formed within the silicon region on a second side of the optically absorptive region. An optical waveguide is formed along a side of the optically absorptive region and spaced apart from the optically absorptive region. The optical waveguide is separated from the light incidence end of the optically absorptive region by a first distance. The optical waveguide is separated from the distal end of the optically absorptive region by a second distance that is less than the first distance.

### CROSS-REFERENCE TO RELATED APPLICATIONS

This claims priority under 35 U.S.C. 119(e) to U.S. Provisional Patent Application No. 63/547,174, filed on Nov. 3, 2023, the disclosure of which is incorporated herein by reference in its entirety for all purposes.

### BACKGROUND OF THE INVENTION

Optical data communication systems operate by modulating laser light to encode digital data patterns within optical signals. The modulated laser light is transmitted through an optical data network from a sending node to a receiving node. The modulated laser light having arrived at the receiving node is de-modulated to obtain the original digital data patterns from the optical signals. The transmission of light through the optical data network includes transmission of light through optical fibers and transmission of light between optical fibers and photonic integrated circuits. In some embodiments, a photodiode is used to detect light of an optical data signal and convert the detected light into a photocurrent that can be processed through electrical circuitry to demodulate the optical data signal to obtain the original digital data pattern from the optical data signal. It is within this context that the present invention arises.

### SUMMARY OF THE INVENTION

In an example embodiment, an integrated photodetector device is disclosed. The integrated photodetector device includes a silicon region. The integrated photodetector device also includes an optically absorptive region formed within the silicon region. The optically absorptive region has a light incidence end and a distal end. A light propagation direction extends from the light incidence end to the distal end. The integrated photodetector device also includes a first doped region formed within the silicon region on a first side of the optically absorptive region. The first doped region includes a first dopant material. The integrated photodetector device also includes a second doped region formed within the silicon region on a second side of the optically absorptive region. The second doped region includes a second dopant material. The integrated photodetector device also includes an optical waveguide formed along a side of the optically absorptive region and spaced apart from the optically absorptive region. The optical waveguide is separated from the light incidence end of the optically absorptive region by a first distance. The optical waveguide is separated from the distal end of the optically absorptive region by a second distance that is less than the first distance.

In an example embodiment, an integrated photodetector device is disclosed. The integrated photodetector device includes a silicon region. The integrated photodetector device also includes an optically absorptive region formed within the silicon region. The optically absorptive region has a light incidence end and a distal end. A light propagation direction extends from the light incidence end to the distal end. The integrated photodetector device also includes a first doped region formed within the silicon region on a first side of the optically absorptive region. The first doped region includes a first dopant material. The integrated photodetector device also includes a second doped region formed within the silicon region on a second side of the optically absorptive region. The second doped region includes a second dopant material. The integrated photodetector device also includes an optical waveguide formed along a side of the optically absorptive region. An outer side of the optical waveguide that is positioned farthest away from the optically absorptive region is configured to taper in a direction away from the optically absorptive region along an initial portion of a length of the optically absorptive region as measured in a direction of light propagation through the optical waveguide. The outer side of the optical waveguide is configured to taper in a direction toward the optically absorptive region along a terminal portion of the length of the optically absorptive region as measured in the direction of light propagation through the optical waveguide. The terminal portion of the length of the optically absorptive region is located after the initial portion of the length of the optically absorptive region in the direction of light propagation through the optical waveguide.

In an example embodiment, an integrated photodetector device is disclosed. The integrated photodetector device includes a silicon region. The integrated photodetector device also includes an optically absorptive region formed within the silicon region. The optically absorptive region has a light incidence end and a distal end. A light propagation direction extends from the light incidence end to the distal end. The integrated photodetector device also includes a first doped region formed within the silicon region on a first side of the optically absorptive region. The first doped region includes a first dopant material. The integrated photodetector device also includes a second doped region formed within the silicon region on a second side of the optically absorptive region. The second doped region includes a second dopant material. The integrated photodetector device also includes an optical waveguide formed at a vertical level above and proximate to the optically absorptive region. The optical waveguide is spaced apart from the optically absorptive region. A distance between a centerline of the optical waveguide and a centerline of the optically absorptive region monotonically decreases along a length of the optically absorptive region in a direction from the light incidence end of the optically absorptive region to the distal end of the optically absorptive region.

In an example embodiment, a method for manufacturing an integrated photodetector device is disclosed. The method includes forming an optically absorptive region within a silicon region. The optically absorptive region has a light incidence end and a distal end. A light propagation direction extends along a length of the optically absorptive region from the light incidence end to the distal end. The method also includes forming a first doped region within the silicon region on a first side of the optically absorptive region. The first doped region includes a first dopant material. The method also includes forming a second doped region within the silicon region on a second side of the optically absorptive region. The second doped region includes a second dopant material. The method also includes forming an optical waveguide along the length of the optically absorptive region and spaced apart from the optically absorptive region. The optical waveguide is formed so that a substantially uniform amount of light couples from the optical waveguide into the optically absorptive region at each location along the length of the optically absorptive region.

### BRIEF DESCRIPTION OF THE DRAWINGS

FIG. 1A shows a schematic of photon absorption in a semiconductor photodetector, in accordance with some embodiments.

FIG. 1B shows a schematic of photon absorption in an avalanche semiconductor photodetector, in accordance with some embodiments.

FIG. 2A shows a perspective view of an integrated photodetector device, in accordance with some embodiments.

FIG. 2B shows a y-direction vertical cross-section view in the y-z plane of the integrated photodetector device, referenced as View A-A in FIG. 2A, along with an example of a dopant distribution within the integrated photodetector device, in accordance with some embodiments.

FIG. 2C shows both a top view of the integrated photodetector device of FIG. 2A, and an example distribution of photocurrent (I) generated along the length of the optically absorptive region extending in the x-direction from the optical waveguide, in accordance with some embodiments.

FIG. 3A shows a top view of an integrated photodetector device, showing an example distribution of photocurrent (I) generated along the length of the optically absorptive region extending in the x-direction from the light incidence end to the distal end, in accordance with some embodiments.

FIG. 3B shows another top view of the integrated photodetector device, in accordance with some embodiments.

FIG. 3C shows a y-direction vertical cross-section view of the integrated photodetector device, referenced as View A-A in FIG. 3B, in accordance with some embodiments.

FIG. 4A shows a top view of an integrated photodetector device, in accordance with some embodiments.

FIG. 4B shows a y-direction vertical cross-section view of the integrated photodetector device, referenced as View A-A in FIG. 4A, in accordance with some embodiments.

FIG. 4C shows a design layout of the integrated photodetector device that includes a p− doped region within the silicon region below the optically absorptive region, such as shown in FIG. 2B, in accordance with some embodiments.

FIG. 4D shows a design layout of the integrated photodetector device that does not include the p− doped region within the silicon region below the optically absorptive region, in accordance with some embodiments.

FIG. 5A shows a top view of an integrated photodetector device, in accordance with some embodiments.

FIG. 5B shows a y-direction vertical cross-section view of the integrated photodetector device, referenced as View A-A in FIG. 5A, in accordance with some embodiments.

FIG. 6 shows an incoming optical intensity splitting configuration in which incoming optical intensity is split and conveyed into two separate integrated photodetector devices, in accordance with some embodiments.

FIG. 7 shows an incoming optical intensity splitting configuration in which incoming optical intensity is split and conveyed into two separate ends of a same integrated photodetector device, in accordance with some embodiments.

FIG. 8 shows an incoming optical intensity splitting configuration in which incoming optical intensity is split and conveyed into two separate integrated photodetector devices, in accordance with some embodiments.

FIG. 9 shows a flowchart of a method for manufacturing an integrated photodetector device, in accordance with some embodiments.

### DETAILED DESCRIPTION OF THE INVENTION

In the following description, numerous specific details are set forth in order to provide an understanding of the embodiments disclosed herein. It will be apparent, however, to one skilled in the art that the embodiments disclosed herein may be practiced without some or all of these specific details. In other instances, well known process operations have not been described in detail in order not to unnecessarily obscure the disclosed embodiments.

The various embodiments disclosed herein relate to optical data communication. More specifically, various embodiments are disclosed herein for an integrated avalanche photodetector is which optical power is absorbed more evenly in the optical absorption material (typically germanium). The more evenly distributed optical absorption is beneficial for avalanche photodetectors because it reduces gain-saturation by lowering gain at higher photocurrents.

A semiconductor photodetector absorbs photons and in turn creates an electron-hole pair for each photon that is absorbed. A voltage is applied across the photodetector to create an electric field that drives the generated electron and hole to respective electrodes of the photodetector, thus generating a photocurrent. Typical photodetectors will generate one electron-hole pair for each absorbed photon.

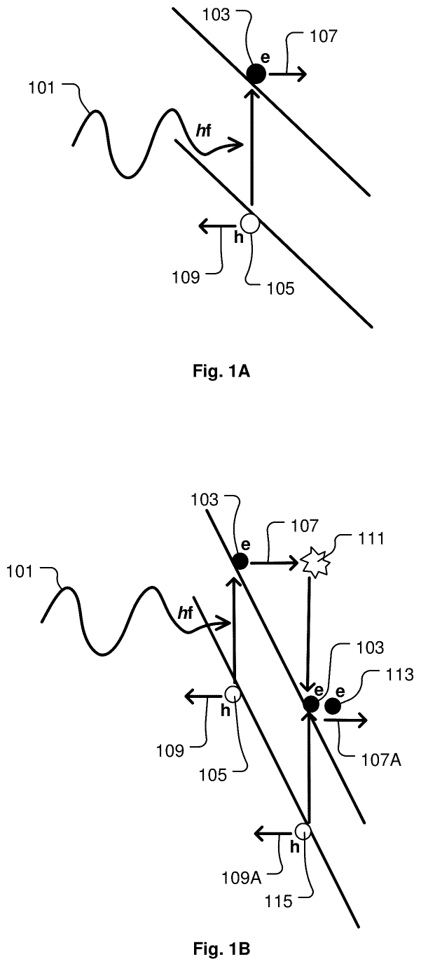

FIG. 1A shows a schematic of photon absorption in a semiconductor photodetector, in accordance with some embodiments. A photon 101 is absorbed within an optical absorption material (typically germanium). Absorption of the photon 101 causes creation of an electron-hole pair that includes an electron 103 and a hole 105. The voltage applied across the photodetector drives the electron 103 toward a first electrode, as indicated by arrow 107. The voltage applied across the photodetector also drives the hole 105 toward a second electrode, as indicated by arrow 109.

An avalanche photodetector is configured to generate more electron-hole pairs per photon by relying on impact ionization. When a hole or electron moves in a high electric field it can pick up enough kinetic energy to form a new electron-hole pair in a collision. This process is called impact ionization. If a photodiode has a high enough electric field, a charge carrier generated by photon absorption can generate a second electron-hole pair by impact ionization, which in turn can generate more electron-hole pairs, and so on, which causes an avalanche effect. Due to this avalanche effect, one photon absorption can result in multiple electron-hole pairs and thus a higher electrical current generation per photon within the photodetector.

FIG. 1B shows a schematic of photon absorption in an avalanche semiconductor photodetector, in accordance with some embodiments. The electric field is sufficiently strong to impart enough kinetic energy to the electron 103 as it travels in the direction 107 toward the first electrode to cause an impact ionization 111, which generates a second electron-hole pair that includes an electron 113 and a hole 115. Both of the electron 103 and the electron 113 continue to be drawn toward the first electrode, as indicated by arrow 107A. Similarly, both the hole 105 and the hole 115 continue to be drawn toward the second electrode, as indicated by arrows 109 and 109A, respectively.

Large avalanche photodetectors have a large gain region where the impact ionization occurs. The gain of a photodetector is a measure of the output electrical current of the photodetector divided by the electrical current that is directly produced by the photons incident on the photodetector. In various embodiments, high voltages, e.g., from about 20 Volts (V) to about 100 V, are applied across these large avalanche photodetector devices by way of the first and second electrodes to maintain the avalanche gain. Compact integrated avalanche photodetectors are much smaller and typically need to operate at much lower voltages. Therefore, the gain region of these compact integrated avalanche photodetectors is much smaller than that of the large avalanche photodetectors. At sufficiently low photocurrents, a small gain region can provide enough gain. However, at higher photocurrents, a small gain region becomes less effective, which results in a decrease of the gain.

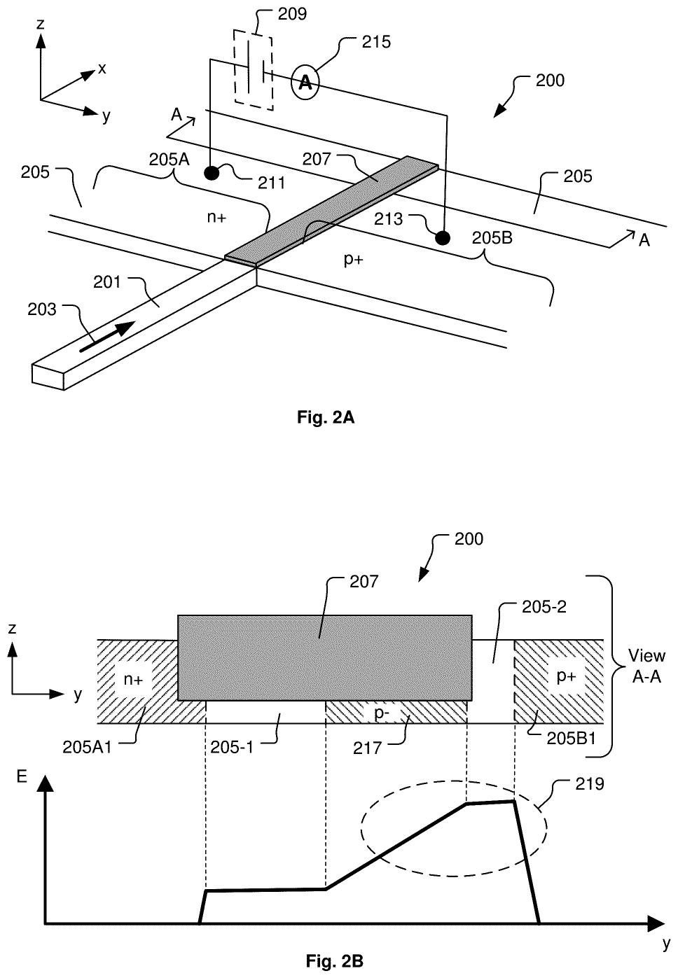

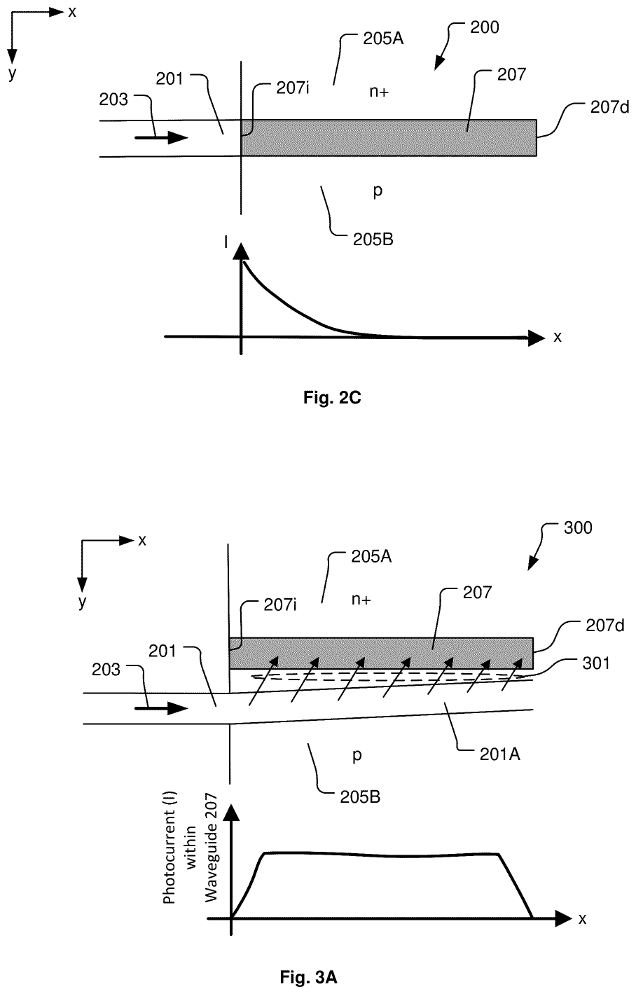

FIG. 2A shows a perspective view of an integrated photodetector device 200, in accordance with some embodiments. Light is conveyed to the integrated photodetector device 200 through an optical waveguide 201, as indicated by arrow 203. The integrated photodetector device 200 is configured as a photodiode formed by a silicon region 205 and an optically absorptive region 207. In some embodiments, the optically absorptive region 207 is formed by germanium. However, in other embodiments, other optically absorptive materials or combinations of materials may be used to form the optically absorptive region 207. The silicon region 205 on one side of the optically absorptive region 207 is doped with a first dopant material to form a first doped region 205A within the silicon region 205. The silicon region 205 on another side of the optically absorptive region 207 is doped with a second dopant material to form a second doped region 205B within the silicon region. The first dopant material and the second dopant material have an opposite electrical polarity, such that the first doped region 205A and the second doped region 205B have the opposite electrical polarity. For example, in some embodiments, the first doped region 205A is an n+ doped region and the second doped region 205B is a p+ doped region, or vice-versa. The first doped region 205A is electrically connected to a first terminal of a voltage source 209, as indicated by electrical connection 211. The second doped region 205B is electrically to a second terminal of the voltage source 209, as indicated by electrical connection 213. An electrical current measurement device 215 is electrically connected within the voltage supply circuit between the voltage source 209 and the integrated photodetector device 200 to provide for measurement of the photocurrent generated within the integrated photodetector device 200.

In general, the voltage source 209 is electrically connected to the integrated photodetector device 200 is a reverse-biased configuration, so that the holes generated in whichever of the first doped region 205A and the second doped region 205B that is a p-type doped region will be pulled away from the optically absorptive region 207 to its electrode (electrical connection 213), and so that the electrons generated in whichever of the first doped region 205A and the second doped region 205B that is an n-type doped region will be also be pulled away from the optically absorptive region 207 to its electrode (electrical connection 211). More specifically, whichever of the first doped region 205A and the second doped region 205B that is a p-type doped region is electrically connected to the negative terminal of the voltage source 209 by way of its electrode (electrical connection 213). And, whichever of the first doped region 205A and the second doped region 205B that is an n-type doped region is electrically connected to the positive terminal of the voltage source 209 by way of its electrode (electrical connection 211). This reverse-biased configuration generates an electric field across the integrated photodetector device 200. The electric field is the highest in the junction region of the integrated photodetector device 200 where the first doped region 205A and the second doped region 205B either interface with each other or are separated from each other by an intrinsic material, such as the material of the optically absorptive region 207. The electrical field that is generated across a particular region of the integrated photodetector device 200 can be adjusted either higher or lower by adjusting the dopant profiles within the first doped region 205A and the second doped region 205B, especially in one or more location(s) near the optically absorptive region 207.

FIG. 2B shows a y-direction vertical cross-section view in the y-z plane of the integrated photodetector device 200, referenced as View A-A in FIG. 2A, along with an example of a dopant distribution within the integrated photodetector device 200, in accordance with some embodiments. The example dopant distribution includes an n+ doped region 205A1 on a first side of the optically absorptive region 207, a p+ doped region 205B1 on a second side of the optically absorptive region 207, and a p− doped region 217 within the silicon region 205 below the optically absorptive region 207. The p− doped region 217 is separated from the n+ doped region 205A1 by a first non-doped portion of the silicon region 205-1. Similarly, the p− doped region 217 is separated from the p+ doped region 205B1 by a second non-doped portion of the silicon region 205-2. The p− doped region 217 is formed within a gain region of the integrated photodetector device 200.

FIG. 2B also shows an example plot of the electrical field strength (E) across the

integrated photodetector device 200, relative to the y-direction vertical cross-section view of the integrated photodetector device 200, in accordance with some embodiments. The dopant distribution shown in FIG. 2B creates a high electrical field 219 within the silicon region 205 on the side of the optically absorptive region 207 next to the p+ doped region 205B1. During operation, avalanche gain of the integrated photodetector device 200 is isolated in this high electrical field 219 region of the integrated photodetector device 200.

FIG. 2C shows both a top view of the integrated photodetector device 200 of FIG. 2A, and an example distribution of photocurrent (I) generated along the length of the optically absorptive region 207 extending in the x-direction from the optical waveguide 201, in accordance with some embodiments. As shown in FIG. 2C, the generated photocurrent (I) decays exponentially along the length of the optically absorptive region 207 in the x-direction as the incoming photons get absorbed within the optically absorptive region 207. In this configuration, the generated photocurrent (I) is non-uniform along the length of the optically absorptive region 207 in the x-direction. More specifically, the generated photocurrent (I) is high at a light incidence end 207i of the optically absorptive region 207 next to the optical waveguide 201. Also, the generated photocurrent (I) is low at a distal end 207d of the optically absorptive region 207 away from the optical waveguide 201. The photocurrent (I) generation distribution causes the local electrical photocurrent (I) density in the gain region of the integrated photodetector device 200 to be unequal along the length of the optically absorptive region 207 as measured in the x-direction.

Various embodiments are disclosed herein for integrated photodetector devices that provide for more uniform (more equal) distribution of electrical photocurrent (I) density along the length of the optically absorptive region, e.g., 207, in the light propagation direction within the integrated photodetector devices. The more uniform (more equal) distribution of electrical photocurrent (I) density along the length of the optically absorptive region, e.g., 207, in the light propagation direction, within the integrated photodetector devices provides for avoidance of gain saturation and achievement of gain at higher electrical currents within the integrated photodetector devices.

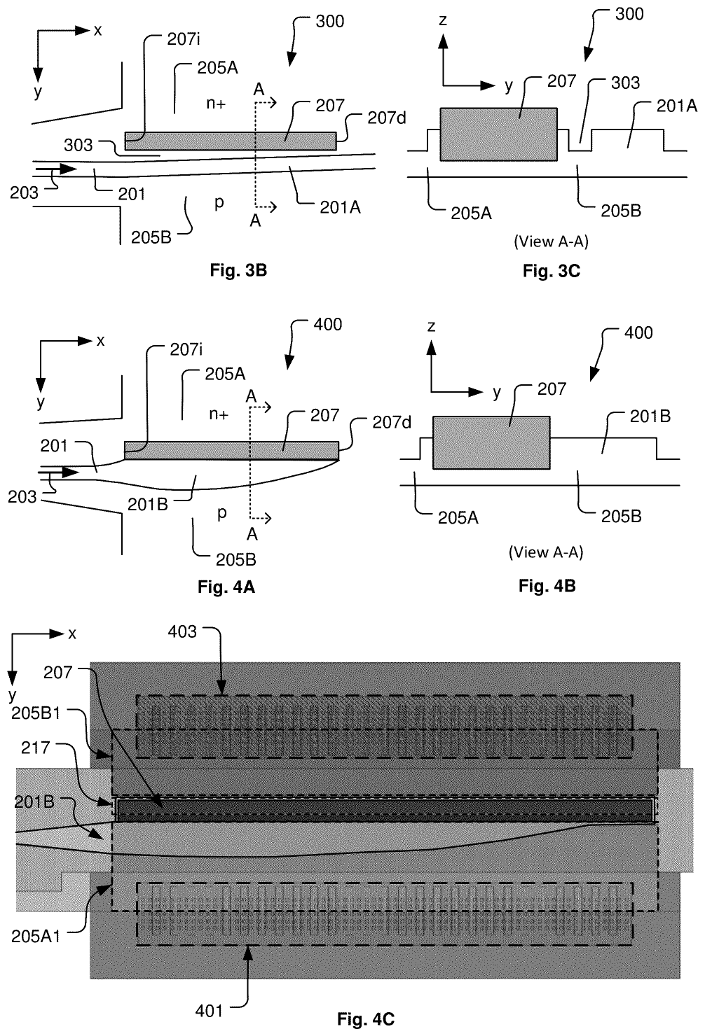

FIG. 3A shows a top view of an integrated photodetector device 300, showing an example distribution of photocurrent (I) generated along the length of the optically absorptive region 207 extending in the x-direction from the light incidence end 207i to the distal end 207d, in accordance with some embodiments. The integrated photodetector device 300 is a variation of the integrated photodetector device 200. Specifically, the optical waveguide 201 is offset in the y-direction (sideways direction) from the light incidence end 207i of the optically absorptive region 207. The optical waveguide 201 includes an adjoining segment 201A that continues alongside the optically absorptive region 207. The adjoining segment 201A of the optical waveguide 201 is positioned close enough to the optically absorptive region 207 so that light will enter into the side of the optically absorptive region 207 as the light propagates along the adjoining segment 201A of the optical waveguide 201 in the x-direction, as indicated by arrows 301.

The adjoining segment 201A of the optical waveguide 201 is configured to be positioned closer to the optically absorptive region 207 with increased distance from the light incidence end 207i of the optically absorptive region 207 toward the distal end 207d of the optically absorptive region 207. In this manner, the ability of light to enter into the optically absorptive region 207 from the adjoining segment 201A of the optical waveguide 201 increases with increased distance from the light incidence end 207i of the optically absorptive region 207 toward the distal end 207d of the optically absorptive region 207. Therefore, as the light intensity within the adjoining segment 201A of the optical waveguide 201 decreases with increased distance from the light incidence end 207i of the optically absorptive region 207 toward the distal end 207d of the optically absorptive region 207, the ability of light to enter into the optically absorptive region 207 from the adjoining segment 201A of the optical waveguide 201 correspondingly increases, which provides for entry of a substantially uniform amount of light into the optically absorptive region 207 as a function of distance from the light incidence end 207i of the optically absorptive region 207 toward the distal end 207d of the optically absorptive region 207. This substantially uniform amount of light entry into the optically absorptive region 207 along the length of the optically absorptive region 207 in turn provides for a substantially uniform amount of photocurrent (I) generation along the length of the optically absorptive region 207, as measured in the x-direction, such as shown in the plot of photocurrent (I) versus x-direction distance along the optically absorptive region 207 in FIG. 3A. It should be understood that by optically coupling light into the optically absorptive region 207 from the side of the optically absorptive region 207, the integrated photodetector device 300 is configured to control the amount and uniformity of light that couples into the optically absorptive region 207 as a function of distance along the length of the optically absorptive region 207, and correspondingly control the amount and uniformity of photocurrent (I) generation along the length of the optically absorptive region 207 in the x-direction (in the light propagation direction).

FIG. 3B shows another top view of the integrated photodetector device 300, in accordance with some embodiments. The adjoining segment 201A of the optical waveguide 201 is integrally formed with the optical waveguide 201 that approaches the integrated photodetector device 300 to convey light into the optically absorptive region 207. In some embodiments, the adjoining segment 201A of the optical waveguide 201 is separated from the optically absorptive region 207 by shallow etched region 303 of the silicon region 205. FIG. 3C shows a y-direction vertical cross-section view of the integrated photodetector device 300, referenced as View A-A in FIG. 3B, in accordance with some embodiments. FIG. 3C shows the adjoining segment 201A of the optical waveguide 201 formed as a shallow etched waveguide within the silicon region 205. FIG. 3C also shows the shallow etched region 303 within the silicon region 205 between the adjoining segment 201A of the optical waveguide 201 and the optically absorptive region 207.

In accordance with the embodiments shown in FIGS. 3A through 3C, the integrated photodetector device 300 includes the silicon region 205, the optically absorptive region 207, the first doped region 205A, the second doped region 205B, and the optical waveguide 201A (adjoining segment 201A of the optical waveguide 201). The optically absorptive region 207 is formed within the silicon region 205. The optically absorptive region 207 has the light incidence end 207i and the distal end 207d. A light propagation direction extends from the light incidence end 207i to the distal end 207d. The first doped region 205A is formed within the silicon region 205 on a first side of the optically absorptive region 207. The first doped region silicon region 205 on a second side of the optically absorptive region 207. The second doped region 205B includes the second dopant material. In some embodiments, the second dopant material is different than the first dopant material, such that the first doped region 205A and the second doped region 205B have opposite electrical polarity with respect to each other. The optical waveguide 201A is formed along a side of the optically absorptive region 207 and is spaced apart from the optically absorptive region 207. The optical waveguide 201A is separated from the light incidence end 207i of the optically absorptive region 207 by a first distance. The optical waveguide 201A is separated from the distal end 207d of the optically absorptive region 207 by a second distance that is less than the first distance.

In some embodiments, a distance between the optical waveguide 201A and the optically absorptive region 207 monotonically decreases along the length of the optically absorptive region 207 in the direction from the light incidence end 207i of the optically absorptive region 207 to the distal end 207d of the optically absorptive region 207. In some embodiments, the optically absorptive region 207 has a substantially linear shape along the length of the optically absorptive region 207 in the direction from the light incidence end 207i of the optically absorptive region 207 to the distal end 207d of the optically absorptive region 207. In some of these embodiments, the optical waveguide 201A has a substantially linear shape along the length of the optically absorptive region 207 in the direction from the light incidence end 207i of the optically absorptive region 207 to the distal end 207d of the optically absorptive region 207. In some embodiments, a variation in a separation distance between the optical waveguide 201A and the optically absorptive region 207 along the length of the optically absorptive region 207 from the light incidence end 207i of the optically absorptive region 207 to the distal end 207d of the optically absorptive region 207 is set so that a substantially uniform amount light couples into the optically absorptive region 207 from the optical waveguide 201A along the length of the optically absorptive region 207 from the light incidence end 207i of the optically absorptive region 207 to the distal end 207d of the optically absorptive region 207.

In some embodiments, the optical waveguide 201A is vertically positioned within a vertical space subtended by the optically absorptive region 207. In some of these embodiments, the silicon region 205 includes a shallow etched region 303 formed between the optically absorptive region 207 and the optical waveguide 201A. In some embodiments, a top surface of the optical waveguide 201A is positioned vertically higher than a bottom surface of the shallow etched region 303. In some embodiments, the optical waveguide 201A does not physically contact the optically absorptive region 207.

In some embodiments, the optically absorptive region 207 is formed of germanium within the integrated photodetector device 300. In some embodiments of the integrated photodetector device 300, the first doped region 205A is an n+ doped region 205A1, and the second doped region 205B is a p+ doped region 205B1, and the silicon region 205 includes a p− doped region 217 formed below the optically absorptive region 207. In some embodiments of the integrated photodetector device 300, the p− doped region 217 is separated from the n+ doped region 205A1 by a first non-doped portion 205-1 of the silicon region 205 located below the optically absorptive region 207, and the p− doped region 217 is separated from the p+ doped region 205B1 by a second non-doped portion 205-2 of the silicon region 205 located beside the optically absorptive region 207. In some embodiments, the p− doped region 217 is located within a gain region of the integrated photodetector device 300. The integrated photodetector device 300 also includes a first electrode (electrical connection 211) electrically connected to the first doped region 205A, and electrically connected to the first terminal of the voltage source 209. The integrated photodetector device 300 also includes a second electrode (electrical connection 213) electrically connected to the second doped region 205B, and electrically connected to the second terminal of the voltage source 209.

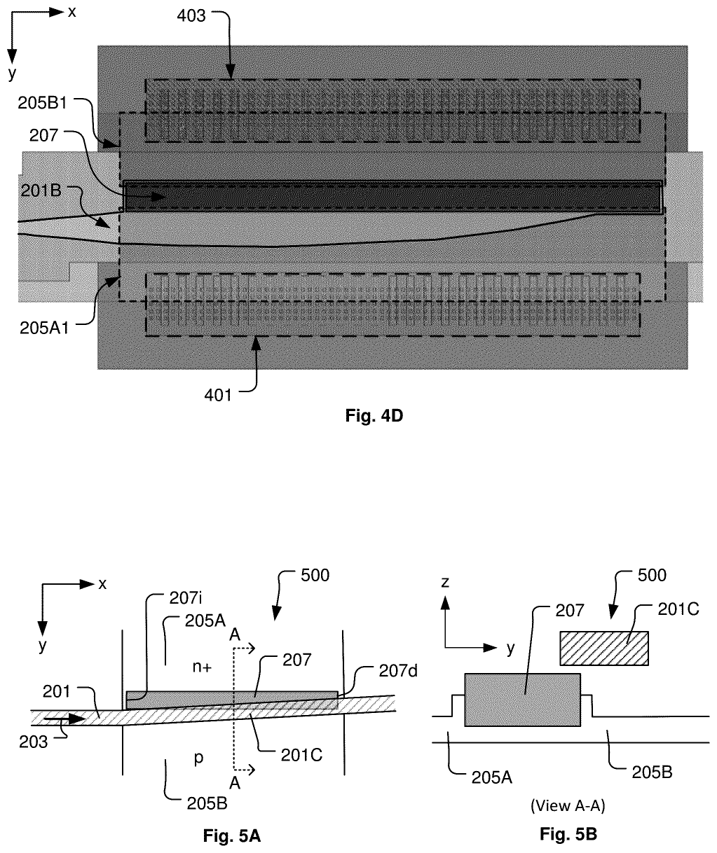

FIG. 4A shows a top view of an integrated photodetector device 400, in accordance with some embodiments. FIG. 4B shows a y-direction vertical cross-section view of the integrated photodetector device 400, referenced as View A-A in FIG. 4A, in accordance with some embodiments. In the integrated photodetector device 400, an adjoining segment 201B of the optical waveguide 201 is formed as part of a larger shallowed etched portion of the silicon region 205 that includes the optically absorptive region 207. In this manner, the adjoining segment 201B of the optical waveguide 201 is directly connected to the optically absorptive region 207. Within the horizontal plane (x-y plane), the adjoining segment 201B of the optical waveguide 201 tapers away from the optically absorptive region 207 as the optical waveguide 201 proceeds from the light incidence end 207i of the optically absorptive region 207 along an initial portion of the length of the optically absorptive region 207 relative to the light propagation direction (x-direction) through the adjoining segment 201B of the optical waveguide 201, as indicated by arrow 203. Further, within the horizontal plane (x-y plane), the adjoining segment 201B of the optical waveguide 201 tapers back toward the optically absorptive region 207 as the optical waveguide 201 proceeds along a remaining length of the optically absorptive region 207 toward the distal end 207d of the optically absorptive region 207 relative to the light propagation direction (x-direction) through the adjoining segment 201B of the optical waveguide 201, as indicated by arrow 203. In some embodiments, the tapered shape of the adjoining segment 201B of the optical waveguide 201 along the length of the optically absorptive region 207 (in the x-direction) is defined to achieve substantially uniform conveyance of light from the adjoining segment 201B of the optical waveguide 201 into the optically absorptive region 207 as a function of distance in the light propagation direction (x-direction) along the optically absorptive region 207.

FIG. 4C shows a design layout of the integrated photodetector device 400 that includes a p− doped region 217 within the silicon region 205 below the optically absorptive region 207, such as shown in FIG. 2B, in accordance with some embodiments. FIG. 4C shows the adjoining segment 201B of the optical waveguide 201 having the varying taper shape positioned along the side of the optically absorptive region 207. FIG. 4C also shows that the p− doped region 217 forms a silicon gain region within the integrated photodetector device 400. More specifically, the p− doped region 217 is formed within the silicon region 205 below the optically absorptive region 207, such as shown in FIG. 2B. FIG. 4C also shows the n+ doped region 205A1 on a first side of the optically absorptive region 207, such as shown in FIG. 2B. FIG. 4C also shows the p+ doped region 205B1 on a second side of the optically absorptive region 207, such as shown in FIG. 2B. FIG. 4C also shows an electrode 401 formed in electrical connection with the n+ doped region 205A1 along the first side of the integrated photodetector device 400. FIG. 4C also shows an electrode 403 formed in electrical connection with the p+ doped region 205B1 along the second side of the integrated photodetector device 400.

FIG. 4D shows a design layout of the integrated photodetector device 400 that does not include the p− doped region 217 within the silicon region 205 below the optically absorptive region 207, in accordance with some embodiments. In the example embodiment of FIG. 4D, the n+ doped region 205A1 along the first side of the integrated photodetector device 400 extends to and along the side of the optically absorptive region 207. Also, in the example embodiment of FIG. 4D, the p+ doped region 205B1 extends to and along the second side of the optically absorptive region 207.

In accordance with the embodiments shown in FIGS. 4A through 4D, the integrated photodetector device 400 includes the silicon region 205, the optically absorptive region 207, the first doped region 205A, the second doped region 205B, and the optical waveguide 201B (adjoining segment 201B of the optical waveguide 201). The optically absorptive region 207 is formed within the silicon region 205. The optically absorptive region 207 has a light incidence end 207i and a distal end 207d. The light propagation direction extends from the light incidence end 207i to the distal end 207d. The first doped region 205A is formed within the silicon region 205 on the first side of the optically absorptive region 207. The first doped region 205A includes the first dopant material. The second doped region 205B is formed within the silicon region 205 on the second side of the optically absorptive region 207. The second doped region 205B includes a second dopant material. In some embodiments, the second dopant material is different than the first dopant material, such that the first doped region 205A and the second doped region 205B have opposite electrical polarity with respect to each other. The optical waveguide 201B is formed along a side of the optically absorptive region 207. In some embodiments, the optical waveguide 201B is vertically positioned within a vertical space subtended by the optically absorptive region 207. An outer side of the optical waveguide 201B that is positioned farthest away from the optically absorptive region 207 is configured to taper in a direction away from the optically absorptive region 207 along an initial portion of a length of the optically absorptive region 207 as measured in a direction of light propagation through the optical waveguide 201B. The outer side of the optical waveguide 201B is configured to taper in a direction toward the optically absorptive region 207 along a terminal portion of the length of the optically absorptive region 207 as measured in the direction of light propagation through the optical waveguide 201B. The terminal portion of the length of the optically absorptive region 207 is located after the initial portion of the length of the optically absorptive region 207 in the direction of light propagation through the optical waveguide 201B. In some embodiments, the terminal portion of the length of the optically absorptive region 207 begins at about a midpoint of the length of the optically absorptive region 207.

In some embodiments, an inner side of the optical waveguide 201B that is positioned closest to the optically absorptive region 207 is in physical contact with the side of the optically absorptive region 207. In some embodiments, the taper of the optical waveguide 201B has a curvilinear shape along the length of the optically absorptive region 207. In some embodiments, the optical waveguide 201B has a width as measured between the inner side of the optical waveguide 201B and the outer side of the optical waveguide 201B in a direction perpendicular to the light propagation direction through the optical waveguide 201B, where the width of the optical waveguide 201B varies along the length of the optically absorptive region 207. In some of these embodiments, the optical waveguide 201B tapers to a point at the distal end 207d of the optically absorptive region 207, such that the outer side of the optical waveguide 201B meets the inner side of the optical waveguide 201B at the distal end 207d of the optically absorptive region 207. In some embodiments, a variation in the width of the optical waveguide 201B along the length of the optically absorptive region 207 from the light incidence end 207i of the optically absorptive region 207 to the distal end 207d of the optically absorptive region 207 is set so that a substantially uniform amount light couples into the optically absorptive region 207 from the optical waveguide 201B along the length of the optically absorptive region 207 from the light incidence end 207i of the optically absorptive region 207 to the distal end 207d of the optically absorptive region 207.

In some embodiments, the optically absorptive region 207 is formed of germanium within the integrated photodetector device 400. In some embodiments of the integrated photodetector device 400, the first doped region 205A is an n+ doped region 205A1, and the second doped region 205B is a p+ doped region 205B1, and the silicon region 205 includes a p− doped region 217 formed below the optically absorptive region 207. In some embodiments of the integrated photodetector device 400, the p− doped region 217 is separated from the n+ doped region 205A1 by a first non-doped portion 205-1 of the silicon region 205 located below the optically absorptive region 207, and the p− doped region 217 is separated from the p+ doped region 205B1 by a second non-doped portion 205-2 of the silicon region 205 located beside the optically absorptive region 207. In some embodiments, the p− doped region 217 is located within a gain region of the integrated photodetector device 400. The integrated photodetector device 400 also includes a first electrode (electrical connection 211) electrically connected to the first doped region 205A, and electrically connected to the first terminal of the voltage source 209. The integrated photodetector device 400 also includes a second electrode (electrical connection 213) electrically connected to the second doped region 205B, and electrically connected to the second terminal of the voltage source 209.

FIG. 5A shows a top view of an integrated photodetector device 500, in accordance with some embodiments. FIG. 5B shows a y-direction vertical cross-section view of the integrated photodetector device 500, referenced as View A-A in FIG. 5A, in accordance with some embodiments. FIG. 5B shows that in the integrated photodetector device 500 an adjoining segment 201C of the optical waveguide 201 is formed on a different vertical plane (in the z-direction) than the optically absorptive region 207. The adjoining segment 201C of the optical waveguide 201 is positioned close enough to the optically absorptive region 207 so that light will evanescently enter into (optically couple into) the optically absorptive region 207 as the light propagates along the adjoining segment 201C of the optical waveguide 201 in the x-direction. The adjoining segment 201C of the optical waveguide 201 is configured to be positioned in the x-y horizontal plane closer to a centerline of the optically absorptive region 207 with increased distance along the adjoining segment 201C of the optical waveguide 201 from the light incidence end 207i of the optically absorptive region 207 toward the distal end 207d of the optically absorptive region 207. In this manner, an amount of vertical overlap of the optically absorptive region 207 by the adjoining segment 201C of the optical waveguide 201 increases with increased distance along the optically absorptive region 207 in the direction extending from the light incidence end 207i of the optically absorptive region 207 toward the distal end 207d of the optically absorptive region 207. In this manner, the ability of light to evanescently enter into (optically couple into) the optically absorptive region 207 from the adjoining segment 201C of the optical waveguide 201 increases with increased distance from the light incidence end 207i of the optically absorptive region 207 toward the distal end 207d of the optically absorptive region 207. The increased overlap of the optically absorptive region 207 by the adjoining segment 201C of the optical waveguide 201 provides for more entry of light from the adjoining segment 201C of the optical waveguide 201 into the optically absorptive region 207 as the intensity of propagating light decreases within the adjoining segment 201C of the optical waveguide 201. In some embodiments, the adjoining segment 201C of the optical waveguide 201 is configured and positioned relative to the optically absorptive region 207 such that a substantially uniform amount of light enters into the optically absorptive region 207 from the adjoining segment 201C of the optical waveguide 201 as a function of distance from the light incidence end 207i of the optically absorptive region 207 toward the distal end 207d of the optically absorptive region 207. This substantially uniform amount of light entry into the optically absorptive region 207 along the length of the optically absorptive region 207 in turn provides for a substantially uniform amount of photocurrent (I) generation along the length of the optically absorptive region 207 in the light propagation direction, as measured in the x-direction.

In accordance with the embodiments shown in FIGS. 5A through 5B, the integrated photodetector device 500 includes the silicon region 205, the optically absorptive region 207, the first doped region 205A, the second doped region 205B, and the optical waveguide 201C (adjoining segment 201C of the optical waveguide 201). The optically absorptive region 207 is formed within the silicon region 205. The optically absorptive region 207 has a light incidence end 207i and a distal end 207d. The light propagation direction extends from the light incidence end 207i to the distal end 207d. The first doped region 205A is formed within the silicon region 205 on the first side of the optically absorptive region 207. The first doped region silicon region 205 on the second side of the optically absorptive region 207. The second doped region 205B includes a second dopant material. In some embodiments, the second dopant material is different than the first dopant material, such that the first doped region 205A and the second doped region 205B have opposite electrical polarity with respect to each other. The optical waveguide 201C is formed at a vertical level above and proximate to the optically absorptive region 207. The optical waveguide 201C is spaced apart from the optically absorptive region 207. In some embodiments, a distance between a centerline of the optical waveguide 201C and a centerline of the optically absorptive region 207 monotonically decreases along a length of the optically absorptive region 207 in a direction from the light incidence end 207i of the optically absorptive region 207 to the distal end 207d of the optically absorptive region 207.

In some embodiments, the optical waveguide 201C is vertically separated from the optically absorptive region 207 by a vertically intervening portion of the silicon region 205. In some embodiments, the optically absorptive region 207 has a substantially linear shape along a length of the optically absorptive region 207 in a direction from the light incidence end 207i of the optically absorptive region 207 to the distal end 207d of the optically absorptive region 207. In some embodiments, the optical waveguide 201C has a substantially linear shape along the length of the optically absorptive region 207. In some embodiments, a variation in the distance between the centerline of the optical waveguide 201C and the centerline of the optically absorptive region 207 along the length of the optically absorptive region 207 from the light incidence end 207i of the optically absorptive region to the distal end 207d of the optically absorptive region 207 is set so that a substantially uniform amount light couples into the optically absorptive region 207 from the optical waveguide 201C along the length of the optically absorptive region 207 from the light incidence end 207i of the optically absorptive region 207 to the distal end 207d of the optically absorptive region 207. In some embodiments, a bottom surface of the optical waveguide 201C is oriented substantially parallel to a top surface of the optically absorptive region 207. In some embodiments, the bottom surface of the optical waveguide 201C is physically separated from the top surface of the optically absorptive region 207.

In some embodiments, the optically absorptive region 207 is formed of germanium within the integrated photodetector device 500. In some embodiments of the integrated photodetector device 500, the first doped region 205A is an n+ doped region 205A1, and the second doped region 205B is a p+ doped region 205B1, and the silicon region 205 includes a p− doped region 217 formed below the optically absorptive region 207. In some embodiments of the integrated photodetector device 500, the p− doped region 217 is separated from the n+ doped region 205A1 by a first non-doped portion 205-1 of the silicon region 205 located below the optically absorptive region 207, and the p− doped region 217 is separated from the p+ doped region 205B1 by a second non-doped portion 205-2 of the silicon region 205 located beside the optically absorptive region 207. In some embodiments, the p− doped region 217 is located within a gain region of the integrated photodetector device 500. The integrated photodetector device 500 also includes a first electrode (electrical connection 211) electrically connected to the first doped region 205A, and electrically connected to the first terminal of the voltage source 209. The integrated photodetector device 500 also includes a second electrode (electrical connection 213) electrically connected to the second doped region 205B, and electrically connected to the second terminal of the voltage source 209.

In some embodiments, the optical intensity within the optically absorptive region 207 can be reduced by splitting the incoming optical intensity and by conveying the split portions of the incoming optical intensity into multiple integrated photodetector devices and/or by conveying the split portions of the incoming optical intensity into opposite ends of the same optically absorptive region 207. Each of the integrated photodetector devices 300, 400, and 500 can be implemented in conjunction with the above-mentioned incoming optical intensity splitting.

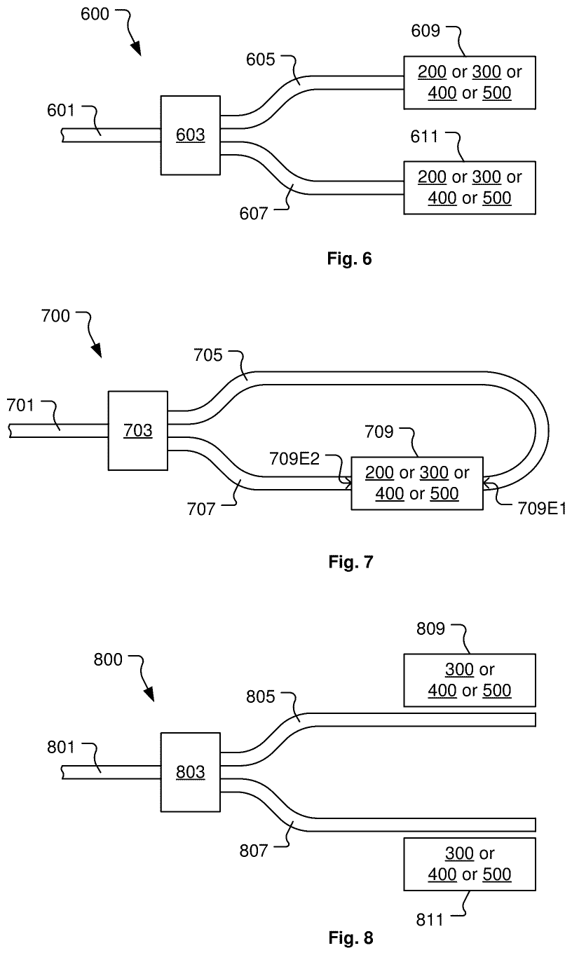

FIG. 6 shows an incoming optical intensity splitting configuration 600 in which incoming optical intensity is split and conveyed into two separate integrated photodetector devices 609 and 611, in accordance with some embodiments. The optical intensity splitting configuration 600 includes an input optical waveguide 601, an optical splitter 603, a first split branch optical waveguide 605, and a second split branch optical waveguide 607. The first split branch optical waveguide 605 is optically connected to a first integrated photodetector device 609, which can be either of the integrated photodetector devices 200, 300, 400, and 500. The second split branch optical waveguide 607 is optically connected to a second integrated photodetector device 611, which can be either of the integrated photodetector devices 200, 300, 400, and 500. Incoming light is conveyed through the input optical waveguide 601 and into the optical splitter 603. The optical splitter 603 is configured to split the incoming light so that a first split portion of the incoming optical intensity is conveyed into the first split branch optical waveguide 605, and so that a second split portion of the incoming optical intensity is conveyed into the second split branch optical waveguide 607. In some embodiments, the first split portion of the incoming optical intensity is substantially equal to the second split portion of the incoming optical intensity. In some embodiments, the first split portion of the incoming optical intensity is different than the second split portion of the incoming optical intensity. The first split portion of the incoming optical intensity is conveyed through the first split branch optical waveguide 605 and into the first integrated photodetector device 609, such that the first split portion of the incoming optical intensity is conveyed into the optically absorptive region 207 within the first integrated photodetector device 609. The second split portion of the incoming optical intensity is conveyed through the second split branch optical waveguide 607 and into the second integrated photodetector device 611, such that the second split portion of the incoming optical intensity is conveyed into the optically absorptive region 207 within the second integrated photodetector device 611.

FIG. 7 shows an incoming optical intensity splitting configuration 700 in which incoming optical intensity is split and conveyed into two separate ends 709E1 and 709E2 of a same integrated photodetector device 709, in accordance with some embodiments. In various embodiments, the integrated photodetector device 709 can be either of the integrated photodetector devices 200, 300, 400, and 500. The optical intensity splitting configuration 700 includes an input optical waveguide 701, an optical splitter 703, a first split branch optical waveguide 705, and a second split branch optical waveguide 707. The first split branch optical waveguide 705 is optically connected to a first end 709E1 of the integrated photodetector device 709. The second split branch optical waveguide 707 is optically connected to a second end 709E2 of the integrated photodetector device 709. Incoming light is conveyed through the input optical waveguide 701 and into the optical splitter 703. The optical splitter 703 is configured to split the light so that a first split portion of the incoming optical intensity is conveyed into the first split branch optical waveguide 705, and so that a second split portion of the incoming optical intensity is conveyed into the second split branch optical waveguide 707. In some embodiments, the first split portion of the incoming optical intensity is substantially equal to the second split portion of the incoming optical intensity. In some embodiments, the first split portion of the incoming optical intensity is different than the second split portion of the incoming optical intensity. The first split portion of the incoming optical intensity is conveyed through the first split branch optical waveguide 705 and into the first end 709E1 of the integrated photodetector device 709, such that the first split portion of the incoming optical intensity is conveyed into the optically absorptive region 207 within the integrated photodetector device 709. The second split portion of the incoming optical intensity is conveyed through the second split branch optical waveguide 707 and into the second end 709E2 of the integrated photodetector device 709, such that the second split portion of the incoming optical intensity is conveyed into the optically absorptive region 207 within the integrated photodetector device 709.

FIG. 8 shows an incoming optical intensity splitting configuration 800 in which incoming optical intensity is split and conveyed into two separate integrated photodetector devices 809 and 811, in accordance with some embodiments. The optical intensity splitting configuration 800 includes an input optical waveguide 801, an optical splitter 803, a first split branch optical waveguide 805, and a second split branch optical waveguide 807. The first split branch optical waveguide 805 is optically connected to a first integrated photodetector device 809. In various embodiments, the first integrated photodetector device 809 can be either of the integrated photodetector devices 300, 400, and 500. The second split branch optical waveguide 807 is optically connected to a second integrated photodetector device 811. In various embodiments, the second integrated photodetector device 811 can be either of the integrated photodetector devices 300, 400, and 500. Incoming light is conveyed through the input optical waveguide 801 and into the optical splitter 803. The optical splitter 803 is configured to split the light so that a first split portion of the incoming optical intensity is conveyed into the first split branch optical waveguide 805, and so that a second split portion of the incoming optical intensity is conveyed into the second split branch optical waveguide 807. In some embodiments, the first split portion of the incoming optical intensity is substantially equal to the second split portion of the incoming optical intensity. In some embodiments, the first split portion of the incoming optical intensity is different than the second split portion of the incoming optical intensity. The first split portion of the incoming optical intensity is conveyed through the first split branch optical waveguide 805 and into the first integrated photodetector device 809, such that the first split portion of the incoming optical intensity is conveyed into the side of the optically absorptive region 207 within the first integrated photodetector device 809. The second split portion of the incoming optical intensity is conveyed through the second split branch optical waveguide 807 and into the second integrated photodetector device 811, such that the second split portion of the incoming optical intensity is conveyed into the side of the optically absorptive region 207 within the second integrated photodetector device 811.

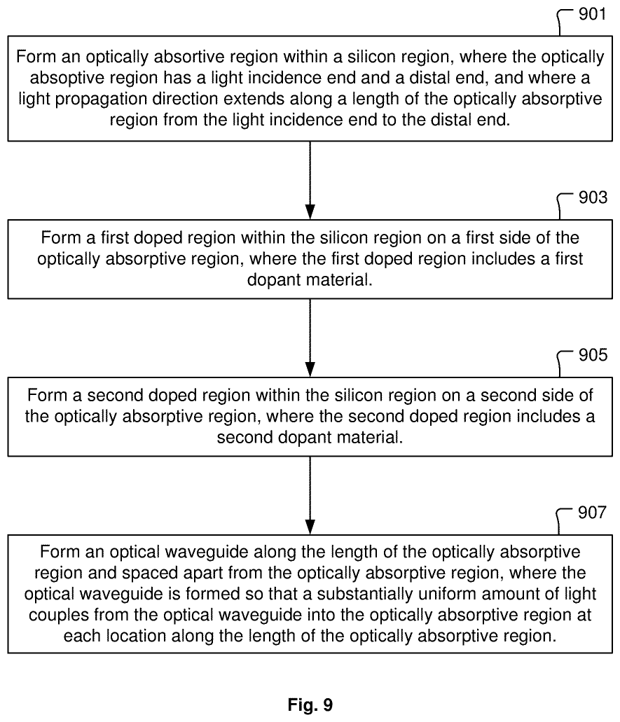

FIG. 9 shows a flowchart of a method for manufacturing an integrated photodetector device, in accordance with some embodiments. The method includes an operation 901 for forming an optically absorptive region, e.g., 207, within a silicon region, e.g., 205. The optically absorptive region has a light incidence end and a distal end. A light propagation direction extends along a length of the optically absorptive region from the light incidence end to the distal end. The method also includes an operation 903 for forming a first doped region, e.g., 205A, within the silicon region on a first side of the optically absorptive region. The first doped region includes a first dopant material. The method also includes an operation 905 for forming a second doped region, e.g., 205B, within the silicon region on a second side of the optically absorptive region. The second doped region includes a second dopant material. In some embodiments, the second dopant material is different than the first dopant material, such that the first doped region 205A and the second doped region 205B have opposite electrical polarity with respect to each other. The method also includes an operation 907 for forming an optical waveguide, e.g., 201, along the length of the optically absorptive region and spaced apart from the optically absorptive region. The optical waveguide is formed so that a substantially uniform amount of light couples from the optical waveguide into the optically absorptive region at each location along the length of the optically absorptive region.

In some embodiments, the method includes positioning of the optical waveguide so that a lengthwise centerline of the optical waveguide is separated from a lengthwise centerline of the optically absorptive region at the light incidence end of the optically absorptive region by a first distance, and so that the lengthwise centerline of the optical waveguide is separated from the lengthwise centerline of the optically absorptive region at the distal end of the optically absorptive region by a second distance that is less than the first distance. In some of these embodiments, the method includes positioning of the optical waveguide next to a side of the optically absorptive region. In some embodiments, the method includes positioning the optical waveguide at a vertical location above the optically absorptive region. In some embodiments, the method includes positioning the optical waveguide so that a portion of the optical waveguide vertically overlaps a corresponding portion of the optically absorptive region. In some embodiments, the method includes varying a width of the optical waveguide along the length of the optically absorptive region, where the width of the optical waveguide is measured between an inner side of the optical waveguide closest to the optically absorptive region and an outer side of the optical waveguide farthest from the optically absorptive region in a direction perpendicular to the light propagation direction along the optical waveguide. In some embodiments, the method includes varying the width of the optical waveguide along the length of the optically absorptive region so that the outer side of the optical waveguide meets the inner side of the optical waveguide at the distal end of the optically absorptive region.

The foregoing description of the embodiments has been provided for purposes of illustration and description, and is not intended to be exhaustive or limiting. Individual elements or features of a particular embodiment are generally not limited to that particular embodiment, but, where applicable, are interchangeable and can be used in a selected embodiment, even if not specifically shown or described. In this manner, one or more features from one or more embodiments disclosed herein can be combined with one or more features from one or more other embodiments disclosed herein to form another embodiment that is not explicitly disclosed herein, but rather that is implicitly disclosed herein. This other embodiment may also be varied in many ways. Such embodiment variations are not to be regarded as a departure from the disclosure herein, and all such embodiment variations and modifications are intended to be included within the scope of the disclosure provided herein.

Although some method operations may be described in a specific order herein, it should be understood that other operations may be performed in between method operations, and/or method operations may be adjusted so that they occur at slightly different times or simultaneously, or may be distributed in a system which allows the occurrence of the processing operations at various intervals associated with the processing, as long as the processing of the method operations are performed in a manner that provides for successful implementation of the method.

Although the foregoing embodiments have been described in some detail for purposes of clarity of understanding, it will be apparent that certain changes and modifications can be practiced within the scope of the appended claims. Accordingly, the embodiments disclosed herein are to be considered as illustrative and not restrictive, and are therefore not to be limited to just the details given herein, but may be modified within the scope and equivalents of the appended claims.

What is claimed is:

1. An integrated photodetector device, comprising:
a silicon region;
an optically absorptive region formed within the silicon region, the optically absorptive region having a light incidence end and a distal end, wherein a light propagation direction extends from the light incidence end to the distal end;
a first doped region formed within the silicon region on a first side of the optically absorptive region, the first doped region including a first dopant material;
a second doped region formed within the silicon region on a second side of the optically absorptive region, the second doped region including a second dopant material; and
an optical waveguide formed along a side of the optically absorptive region and spaced apart from the optically absorptive region, the optical waveguide separated from the light incidence end of the optically absorptive region by a first distance, the optical waveguide separated from the distal end of the optically absorptive region by a second distance that is less than the first distance.

2. The integrated photodetector device as recited in claim 1, wherein a distance between the optical waveguide and the optically absorptive region monotonically decreases along a length of the optically absorptive region in a direction from the light incidence end of the optically absorptive region to the distal end of the optically absorptive region.

3. The integrated photodetector device as recited in claim 1, wherein the optically absorptive region has a substantially linear shape along a length of the optically absorptive region in a direction from the light incidence end of the optically absorptive region to the distal end of the optically absorptive region.

4. The integrated photodetector device as recited in claim 3, wherein the optical waveguide has a substantially linear shape along the length of the optically absorptive region in the direction from the light incidence end of the optically absorptive region to the distal end of the optically absorptive region.

5. The integrated photodetector device as recited in claim 1, wherein a variation in a separation distance between the optical waveguide and the optically absorptive region along a length of the optically absorptive region from the light incidence end of the optically absorptive region to the distal end of the optically absorptive region is set so that a substantially uniform amount light couples into the optically absorptive region from the optical waveguide along the length of the optically absorptive region from the light incidence end of the optically absorptive region to the distal end of the optically absorptive region.

6. The integrated photodetector device as recited in claim 1, wherein the optical waveguide is vertically positioned within a vertical space subtended by the optically absorptive region.

7. The integrated photodetector device as recited in claim 6, wherein the silicon region includes a shallow etched region formed between the optically absorptive region and the optical waveguide, wherein a top surface of the optical waveguide is positioned vertically higher than a bottom surface of the shallow etched region.

8. The integrated photodetector device as recited in claim 1, wherein the optically absorptive region is formed of germanium.

9. The integrated photodetector device as recited in claim 1, wherein the first doped region is an n+ doped region, wherein the second doped region is a p+ doped region, and wherein the silicon region includes a p− doped region formed below the optically absorptive region.

10. The integrated photodetector device as recited in claim 9, wherein the p− doped region is separated from the n+ doped region by a first non-doped portion of the silicon region located below the optically absorptive region, and wherein the p− doped region is separated from the p+ doped region by a second non-doped portion of the silicon region located beside the optically absorptive region.

11. The integrated photodetector device as recited in claim 9, wherein the p− doped region is located within a gain region of the integrated photodetector device.

12. The integrated photodetector device as recited in claim 1, wherein the optical waveguide does not physically contact the optically absorptive region.

13. The integrated photodetector device as recited in claim 1, further comprising:
a first electrode electrically connected to the first doped region, the first electrode electrically connected to a first terminal of a voltage source; and
a second electrode electrically connected to the second doped region, the second electrode electrically connected to a second terminal of the voltage source.

14. An integrated photodetector device, comprising:
a silicon region;
an optically absorptive region formed within the silicon region, the optically absorptive region having a light incidence end and a distal end, wherein a light propagation direction extends from the light incidence end to the distal end;
a first doped region formed within the silicon region on a first side of the optically absorptive region, the first doped region including a first dopant material;
a second doped region formed within the silicon region on a second side of the optically absorptive region, the second doped region including a second dopant material; and
an optical waveguide formed along a side of the optically absorptive region, wherein an outer side of the optical waveguide that is positioned farthest away from the optically absorptive region is configured to taper in a direction away from the optically absorptive region along an initial portion of a length of the optically absorptive region as measured in a direction of light propagation through the optical waveguide, the outer side of the optical waveguide configured to taper in a direction toward the optically absorptive region along a terminal portion of the length of the optically absorptive region as measured in the direction of light propagation through the optical waveguide, wherein the terminal portion of the length of the optically absorptive region is located after the initial portion of the length of the optically absorptive region in the direction of light propagation through the optical waveguide.

15. The integrated photodetector device as recited in claim 14, wherein an inner side of the optical waveguide that is positioned closest to the optically absorptive region is in physical contact with the side of the optically absorptive region.

16. The integrated photodetector device as recited in claim 14, wherein the terminal portion of the length of the optically absorptive region begins at about a midpoint of the length of the optically absorptive region.

17. The integrated photodetector device as recited in claim 14, wherein the taper of the optical waveguide has a curvilinear shape along the length of the optically absorptive region.

18. The integrated photodetector device as recited in claim 14, wherein the optical waveguide has a width as measured between the inner side of the optical waveguide and the outer side of the optical waveguide in a direction perpendicular to the light propagation direction through the optical waveguide, wherein the width of the optical waveguide varies along the length of the optically absorptive region.

19. The integrated photodetector device as recited in claim 18, wherein the optical waveguide tapers to a point at the distal end of the optically absorptive region, such that the outer side of the optical waveguide meets the inner side of the optical waveguide at the distal end of the optically absorptive region.

20. The integrated photodetector device as recited in claim 18, wherein a variation in the width of the optical waveguide along the length of the optically absorptive region from the light incidence end of the optically absorptive region to the distal end of the optically absorptive region is set so that a substantially uniform amount light couples into the optically absorptive region from the optical waveguide along the length of the optically absorptive region from the light incidence end of the optically absorptive region to the distal end of the optically absorptive region.

21. The integrated photodetector device as recited in claim 14, wherein the optical waveguide is vertically positioned within a vertical space subtended by the optically absorptive region.

22. The integrated photodetector device as recited in claim 14, wherein the optically absorptive region is formed of germanium.

23. The integrated photodetector device as recited in claim 14, wherein the first doped region is an n+ doped region, wherein the second doped region is a p+ doped region, and wherein the silicon region includes a p− doped region formed below the optically absorptive region.

24. The integrated photodetector device as recited in claim 23, wherein the p− doped region is separated from the n+ doped region by a first non-doped portion of the silicon region located below the optically absorptive region, and wherein the p− doped region is separated from the p+ doped region by a second non-doped portion of the silicon region located beside the optically absorptive region.

25. The integrated photodetector device as recited in claim 23, wherein the p− doped region is located within a gain region of the integrated photodetector device.

26. The integrated photodetector device as recited in claim 14, further comprising:
a first electrode electrically connected to the first doped region, the first electrode electrically connected to a first terminal of a voltage source; and
a second electrode electrically connected to the second doped region, the second electrode electrically connected to a second terminal of the voltage source.

27. An integrated photodetector device, comprising:
a silicon region;
an optically absorptive region formed within the silicon region, the optically absorptive region having a light incidence end and a distal end, wherein a light propagation direction extends from the light incidence end to the distal end;
a first doped region formed within the silicon region on a first side of the optically absorptive region, the first doped region including a first dopant material;
a second doped region formed within the silicon region on a second side of the optically absorptive region, the second doped region including a second dopant material; and
an optical waveguide formed at a vertical level above and proximate to the optically absorptive region, the optical waveguide spaced apart from the optically absorptive region, wherein a distance between a centerline of the optical waveguide and a centerline of the optically absorptive region monotonically decreases along a length of the optically absorptive region in a direction from the light incidence end of the optically absorptive region to the distal end of the optically absorptive region.

28. The integrated photodetector device as recited in claim 27, wherein the optical waveguide is vertically separated from the optically absorptive region by a vertically intervening portion of the silicon region.

29. The integrated photodetector device as recited in claim 27, wherein the optically absorptive region has a substantially linear shape along a length of the optically absorptive region in a direction from the light incidence end of the optically absorptive region to the distal end of the optically absorptive region.

30. The integrated photodetector device as recited in claim 29, wherein the optical waveguide has a substantially linear shape along the length of the optically absorptive region.

31. The integrated photodetector device as recited in claim 28, wherein a variation in the distance between the centerline of the optical waveguide and the centerline of the optically absorptive region along the length of the optically absorptive region from the light incidence end of the optically absorptive region to the distal end of the optically absorptive region is set so that a substantially uniform amount light couples into the optically absorptive region from the optical waveguide along the length of the optically absorptive region from the light incidence end of the optically absorptive region to the distal end of the optically absorptive region.

32. The integrated photodetector device as recited in claim 27, wherein a bottom surface of the optical waveguide is oriented substantially parallel to a top surface of the optically absorptive region.

33. The integrated photodetector device as recited in claim 32, wherein the bottom surface of the optical waveguide is physically separated from the top surface of the optically absorptive region.

34. The integrated photodetector device as recited in claim 27, wherein the optically absorptive region is formed of germanium.

35. The integrated photodetector device as recited in claim 27, wherein the first doped region is an n+ doped region, wherein the second doped region is a p+ doped region, and wherein the silicon region includes a p− doped region formed below the optically absorptive region.

36. The integrated photodetector device as recited in claim 35, wherein the p− doped region is separated from the n+ doped region by a first non-doped portion of the silicon region located below the optically absorptive region, and wherein the p− doped region is separated from the p+ doped region by a second non-doped portion of the silicon region located beside the optically absorptive region.

37. The integrated photodetector device as recited in claim 35, wherein the p− doped region is located within a gain region of the integrated photodetector device.

38. The integrated photodetector device as recited in claim 27, further comprising:
a first electrode electrically connected to the first doped region, the first electrode electrically connected to a first terminal of a voltage source; and
a second electrode electrically connected to the second doped region, the second electrode electrically connected to a second terminal of the voltage source.

39. A method for manufacturing an integrated photodetector device, comprising:
forming an optically absorptive region within a silicon region, the optically absorptive region having a light incidence end and a distal end, wherein a light propagation direction extends along a length of the optically absorptive region from the light incidence end to the distal end;
forming a first doped region within the silicon region on a first side of the optically absorptive region, the first doped region including a first dopant material;
forming a second doped region within the silicon region on a second side of the optically absorptive region, the second doped region including a second dopant material; and
forming an optical waveguide along the length of the optically absorptive region and spaced apart from the optically absorptive region, the optical waveguide formed so that a substantially uniform amount of light couples from the optical waveguide into the optically absorptive region at each location along the length of the optically absorptive region.

40. The method for manufacturing an integrated photodetector device as recited in claim 39, further comprising:
positioning the optical waveguide so that a lengthwise centerline of the optical waveguide is separated from a lengthwise centerline of the optically absorptive region at the light incidence end of the optically absorptive region by a first distance, and so that the lengthwise centerline of the optical waveguide is separated from the lengthwise centerline of the optically absorptive region at the distal end of the optically absorptive region by a second distance that is less than the first distance.

41. The method for manufacturing an integrated photodetector device as recited in claim 40, further comprising:
positioning the optical waveguide next to a side of the optically absorptive region.

42. The method for manufacturing an integrated photodetector device as recited in claim 40, further comprising:
positioning the optical waveguide at a vertical location above the optically absorptive region.

43. The method for manufacturing an integrated photodetector device as recited in claim 42, further comprising:
positioning the optical waveguide so that a portion of the optical waveguide vertically overlaps a corresponding portion of the optically absorptive region.

44. The method for manufacturing an integrated photodetector device as recited in claim 39, further comprising:
varying a width of the optical waveguide along the length of the optically absorptive region, wherein the width of the optical waveguide is measured between an inner side of the optical waveguide closest to the optically absorptive region and an outer side of the optical waveguide farthest from the optically absorptive region in a direction perpendicular to the light propagation direction along the optical waveguide.

45. The method for manufacturing an integrated photodetector device as recited in claim 44, wherein the outer side of the optical waveguide meets the inner side of the optical waveguide at the distal end of the optically absorptive region.
